(19) United States
(12) Patent Application Publication
(10) Pub. No.: US 2022/0255029 A1
(43) Pub. Date: Aug. 11, 2022

(54) ADHESIVE SHEET, LAYERED SHEET, FLEXIBLE IMAGE DISPLAY DEVICE MEMBER, AND FLEXIBLE IMAGE DISPLAY DEVICE

(71) Applicant: Mitsubishi Chemical Corporation, Tokyo (JP)

(72) Inventors: Yuuko HAYAKAWA, Tokyo (JP); Daiki TABATA, Tokyo (JP); Masaya MINEMOTO, Tokyo (JP)

(73) Assignee: Mitsubishi Chemical Corporation, Tokyo (JP)

(21) Appl. No.: 17/660,434

(22) Filed: Apr. 25, 2022

Related U.S. Application Data
(63) Continuation of application No. PCT/JP2020/042514, filed on Nov. 13, 2020.

(30) Foreign Application Priority Data
Nov. 22, 2019 (JP) 2019-211083
Nov. 22, 2019 (JP) 2019-211084

(51) Int. Cl. H01L 51/50; C09J 133/10; C08F 222/10

(52) U.S. Cl. CPC H01L 51/50; C09J 133/10; C09J 2301/312; C09J 2203/318; C09J 2433/00; C08F 222/1065

(57) ABSTRACT

Provided is a flexible image display device member including an adhesive layer which enables, during a folding operation of a layered sheet having a configuration in which a member sheet and an adhesive sheet are layered in a high-temperature environment, a good restoration property when the layered sheet is unfolded from a folded state. The flexible image display device member has a configuration in which two flexible members are bonded together via the adhesive layer, and the adhesive layer satisfies requirements (1) and (2). (1) A storage shear modulus at 60° C. (G′ (60° C.)) obtained by dynamic viscoelasticity measurement in a shear mode at a frequency of 1 Hz is 0.005 MPa or more and less than 0.20 MPa, and a loss tangent at 60° C. (tan δ (60° C.)) is less than 0.60. (2) When a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

### TECHNICAL FIELD

The present invention relates to an adhesive sheet or an adhesive layer that can be suitably used in an image display device having a curved surface or a bendable image display device or the like, a flexible image display device member, a layered sheet using the adhesive sheet or the adhesive layer, and a flexible image display device using the layered sheet.

### BACKGROUND ART

In recent years, an image display device having a curved surface and a bendable image display device, which use organic light emitting diodes (OLED) or quantum dots (QD), have been developed and are being widely commercialized.

In such a display device, a plurality of sheet members such as a cover lens, a circularly polarizing plate, a touch film sensor, and a light emitting element are bonded together with transparent adhesive sheets to form a layered structure, and when an adhesive sheet is brought into focus, it can be regarded as a layered sheet in which a member sheet and an adhesive sheet are layered.

A foldable bendable image display device has various problems due to an interlayer stress at the time of bending. For example, layers may peel off from each other when folded (delamination; a peeling phenomenon between layers is referred to as “delamination”), and a layered sheet that does not peel off even when folded is required.

In addition, a layered sheet for quickly restoring a screen to a flat state when the screen is unfolded from a folded state is required.

Further, while a folding operation is repeated, a stress is applied to the member sheet which is an adherend of the adhesive sheet, thereby causing cracks and finally breaking, and a layered sheet that is durable against repeated folding operations especially at a low temperature is required.

Regarding the foldable bendable image display device, for example, PTL 1 discloses an adhesive for a repeated bendable device, an adhesive sheet, a bendable layered member, and a repeated bendable device. When the adhesive sheet is applied to the repeated bendable device while setting a product value of a creep compliance fluctuation value and a relaxation elastic modulus fluctuation value within a suitable range, deformation of an adhesive layer after being released from a bent state in a case of being placed in the bent state for a long time is prevented, and a good restoration property that the influence of being placed in the bent state is relaxed is exhibited.

### CITATION LIST

### Patent Literature

PTL 1: JP 2019-123826 A

### SUMMARY OF INVENTION

### Technical Problem

However, even when the product value of the creep compliance fluctuation value and the relaxation elastic modulus fluctuation value of the adhesive sheet is controlled to a suitable range at room temperature as disclosed in PTL 1, there are problems that when the folding operation is performed at a high temperature, the influence of being placed in the bent state remains and the restoration property is insufficient, or that when the folding operation is repeated at a low temperature, the stress is applied to the member sheet which is the adherend of the adhesive sheet, so that the member sheet cracks.

In particular, a device including an adhesive sheet is assumed to be used at a high temperature due to heat generation of the device or to be used at a high temperature and a low temperature in accordance with an environment such as a region or a season, so that an adhesive sheet that stably exhibits the restoration property and durability over a wide temperature range is required.

Even when the product value of the creep compliance fluctuation value and the relaxation elastic modulus fluctuation value of the adhesive sheet is controlled to a suitable range as disclosed in PTL 1, there are problems that an impact due to contact or pressurization cannot be completely absorbed, that the member sheet, which is the adherend of the adhesive sheet, is stressed and scratched, or that an influence of distortion remains and the restoration property is insufficient.

Therefore, a first object of the present invention is to provide a flexible image display device member and a flexible image display device including an adhesive layer which enables, during a folding operation of a layered sheet having a configuration in which a member sheet and an adhesive sheet are layered in a high-temperature environment, a good restoration property when the layered sheet is unfolded from a folded state.

On the other hand, a second object of the present invention is to provide a flexible image display device member and a flexible image display device including an adhesive layer that exhibits good impact resistance that a stress applied to a member sheet can be absorbed to prevent damage even when an impact due to contact or pressurization is received and that has a good restoration property from distortion in a layered sheet having a configuration in which the member sheet and an adhesive sheet are layered.

### Solution to Problem

In order to achieve the first object, the present invention proposes a flexible image display device member I having a configuration in which two flexible members are bonded together via an adhesive layer,

in which the adhesive layer satisfies requirements (1) and (2).

(1) A storage shear modulus at 60° C. (G′ (60° C.)) obtained by dynamic viscoelasticity measurement in a shear mode at a frequency of 1 Hz is 0.005 MPa or more and less than 0.20 MPa, and a loss tangent at 60° C. (tan δ (60° C.)) is less than 0.60.

(2) When a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

In order to achieve the second object, the present invention proposes a flexible image display device member II having a configuration in which two flexible members are bonded together via an adhesive layer,

in which the adhesive layer satisfies requirements (3) and (4).

(3) A maximum value (tan δ (max)) of a loss elastic modulus in a temperature range of −60° C. to 25° C. obtained by dynamic viscoelasticity measurement in a shear mode at a frequency of 1 Hz is 1.5 or more.

(4) When a creep compliance value measured when a stress of 3,000 Pa is applied is set to a minimum creep compliance J(t)min (MPa¹), and a maximum creep compliance value measured during a period in which a stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

The present invention also proposes a flexible image display device including the flexible image display device member I or II.

### Advantageous Effects of Invention

When the creep compliance fluctuation value Δ log J(t) is set to be less than 1.0 and the storage elastic modulus and the loss tangent at 60° C. are adjusted to a specific range, the adhesive layer satisfying the above (1) and (2) can exhibit a good restoration property even in a high-temperature static bending test which is under a condition severer than room temperature. Therefore, the flexible image display device member I proposed in the present invention can exhibit a good restoration property even at a high temperature which is a condition severer than room temperature.

In addition, when the creep compliance fluctuation value Δ log J(t) is set to be less than 1.0 and the maximum value of the loss elastic modulus in the temperature range of −60° C. to 25° C. is adjusted to a specific range, the adhesive layer satisfying the above (3) and (4) can absorb a stress applied to the flexible member, which is an adherend of the adhesive layer, to prevent damage even when an impact due to contact or pressurization is received and can exhibit a good restoration property from distortion. Therefore, the flexible image display device member II proposed in the present invention can prevent the flexible member from being damaged even when receiving the impact due to the contact or pressurization, and can exhibit a good restoration property from distortion.

### DESCRIPTION OF EMBODIMENTS

Next, the present invention will be described based on examples of an embodiment. However, the present invention is not limited to the embodiment described below.

<<Present Adhesive Sheet I>>

An adhesive sheet according to examples of an embodiment of the present invention (hereinafter, may be referred to as the “present adhesive sheet I”) satisfies the following requirements (1) and (2).

(1) In the adhesive sheet, a storage shear modulus at 60° C. (G′ (60° C.)) obtained by dynamic viscoelasticity measurement in a shear mode at a frequency of 1 Hz is 0.005 MPa or more and less than 0.20 MPa, and a loss tangent at 60° C. (tan δ (60° C.)) is less than 0.60.

(2) In the adhesive sheet, when a creep compliance value measured when a stress of 3,000 Pa is applied is set to a minimum creep compliance J(t)min (MPa⁻¹), and a maximum creep compliance value measured during a period in which a stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

<<Present Flexible Image Display Device Member I>>

A flexible image display device member according to an example of the embodiment of the present invention (hereinafter, may be referred to as the “present flexible image display device member I”) has a configuration in which two flexible members are bonded together via an adhesive layer, and the adhesive layer (hereinafter, may be referred to as the “present adhesive layer I”) satisfies the following requirements (1) and (2).

(1) In the adhesive layer, a storage shear modulus at 60° C. (G′ (60° C.)) obtained by dynamic viscoelasticity measurement in a shear mode at a frequency of 1 Hz is 0.005 MPa or more and less than 0.20 MPa, and a loss tangent at 60° C. (tan δ (60° C.)) is less than 0.60.

(2) In the adhesive layer, when a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

<<Present Adhesive Sheet I and Present Adhesive Layer I>>

First, the present adhesive sheet I and the present adhesive layer I will be described.

<Storage Shear Modulus and Loss Tangent>

In the present adhesive sheet I and the present adhesive layer I, the storage shear modulus at 60° C. (G′ (60° C.)) obtained by the dynamic viscoelasticity measurement in the shear mode at a frequency of 1 Hz is preferably 0.005 MPa or more and less than 0.20 MPa.

The storage shear modulus at 60° C. (G′ (60° C.)) of the present adhesive sheet I and the present adhesive layer I is preferably less than 0.20 MPa, more preferably 0.18 MPa or less, still more preferably 0.15 MPa or less, and even more preferably 0.12 MPa or less.

On the other hand, a lower limit of the storage shear modulus (G′ (60° C.)) is preferably 0.005 MPa or more from the viewpoint of shape maintenance.

By setting the storage shear modulus (G′ (60° C.)) in the above range, for example, when the present adhesive sheet I or the present adhesive layer I is attached to a member sheet to form a layered sheet or a flexible image display device member, an interlayer stress at the time of bending the layered sheet or the flexible image display device member in a high temperature from a normal temperature can be reduced, and delamination or cracking of the member sheet or the flexible member can be prevented.

The loss tangent at 60° C. (tan δ (60° C.)) of the present adhesive sheet I and the present adhesive layer I in shear measurement at a frequency of 1 Hz is preferably less than 0.60, more preferably 0.55 or less, and still more preferably 0.50 or less. On the other hand, a lower limit of the loss tangent (tan δ (60° C.)) is preferably 0.20 or more from the viewpoint of adhesive strength maintenance.

By setting the loss tangent (tan δ (60° C.)) in the above range, a flow of the adhesive sheet or the adhesive layer can be prevented, and for example, when the present adhesive sheet I or the present adhesive layer I is attached to a member sheet to form a layered sheet or a flexible image display device member, a restoration property is made good when the layered sheet or the flexible image display device member is unbent from a bent state.

Even when the storage shear modulus (G′ (60° C.)) of the present adhesive sheet I and the present adhesive layer I is less than 0.20 MPa, when the loss tangent (tan δ (60° C.)) is large, creep deformation occurs in the present adhesive sheet I and the present adhesive layer I during high-temperature bending.

However, by setting the loss tangent (tan δ (60° C.)) to be less than 0.60, the creep deformation can be prevented, and the restoration property when the layered sheet or the flexible image display device member is unbent from a bent state can also be made good.

Further, in the present adhesive sheet I and the present adhesive layer I, a storage shear modulus at −20° C. (G′ (−20° C.)) obtained by the dynamic viscoelasticity measurement in the shear mode at a frequency of 1 Hz is preferably 1.0 MPa or less, more preferably 0.70 MPa or less, and still more preferably 0.60 MPa or less. On the other hand, a lower limit of the storage shear modulus (G′ (−20° C.)) is preferably 0.05 MPa or more from the viewpoint of shape maintenance on a high-temperature side.

By setting the storage shear modulus (G′ (−20° C.)) of the present adhesive sheet I and the present adhesive layer I to 1.0 MPa or less, an interlayer stress at the time of bending at a low temperature can be reduced, and delamination or cracking of the member sheet or the flexible member can be prevented.

In general, since the adhesive sheet and the adhesive layer have a glass transition temperature (Tg) between a low temperature and a normal temperature, the storage shear modulus (G′ (−20° C.)) is larger than the storage shear modulus (G′ (60° C.)).

However, if the storage shear modulus (G′ (−20° C.)) is 1.0 MPa or less, the member sheet or the flexible member can be prevented from being cracked even when a bending operation is performed at a low temperature.

<Maximum Point of Loss Tangent (tan δ) and Glass Transition Temperature (Tg)>

The maximum point of the loss tangent of the present adhesive sheet I and the present adhesive layer I is preferably at −25° C. or lower obtained by the dynamic viscoelasticity measurement in the shear mode at a frequency of 1 Hz.

The maximum point of the loss tangent (tan δ) can be interpreted as the glass transition temperature (Tg), and by setting the glass transition temperature (Tg) in the above range, the storage shear modulus (G′ (−20° C.)) of the present adhesive sheet I is easily adjusted to 1.0 MPa or less.

The “glass transition temperature” refers to a temperature at which a main dispersion peak of the loss tangent (tan δ) appears. Therefore, when the maximum point of the loss tangent (tan δ) obtained by the dynamic viscoelasticity measurement in the shear mode at a frequency of 1 Hz is observed only at one point, in other words, when a tan δ curve exhibits a unimodal shape, it can be considered that the glass transition temperature (Tg) is single.

The “maximum point” of the loss tangent (tan δ) means a point having a peak value in the tan δ curve, that is, a maximum value in a predetermined range or the entire range among inflection points at which the value changes from positive (+) to negative (−) at the time of differentiation.

The elastic modulus (storage elastic modulus) G′, a viscosity (loss elastic modulus) G″, and tan δ=G″/G′ at various temperatures can be measured by using a strain rheometer.

The storage shear modulus (G′) and the loss tangent (tan δ) can be adjusted to the above ranges by adjusting types, mass average molecular weights, and the like of resins constituting the present adhesive sheet I and the present adhesive layer I (for example, an acrylic (co)polymer and a curable compound described later), or further adjusting a gel fraction of the adhesive sheet. However, the present invention is not limited to this method.

<Creep Compliance>

In the present adhesive sheet I and the present adhesive layer I, when a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is preferably less than 1.0.

In order to reduce the creep compliance fluctuation value Δ log J(t), in a crosslinked structure of the present adhesive sheet I and the present adhesive layer I, it is preferable to adopt a method for increasing the gel fraction by increasing the number of crosslinking points or forming a molecular chain entangled structure with an increased molecular weight between the crosslinking points by forming a crosslinked structure having a long chain structure.

The creep compliance fluctuation value Δ log J(t) can also be adjusted by adjusting types, mass average molecular weights, and the like of polymers forming the present adhesive sheet I and the present adhesive layer I.

However, the method for adjusting the creep compliance fluctuation value Δ log J(t) is not limited to these methods.

In recent years, due to a demand for weight reduction of an image display device, the member sheet to be used tends to be thin, and it is important to reduce a stress on the member sheet.

Here, examples of the member sheet included in the image display device and to be attached to the present adhesive sheet I and the present adhesive layer I include a sheet containing a cycloolefin resin, a triacetyl cellulose resin, a polymethyl methacrylate resin, an epoxy resin, and a polyimide resin as a main component.

Among them, tensile strength at 25° C. of a sheet containing a cycloolefin resin as a main component is as low as 40 MPa to 60 MPa at a thickness of 100 lam, and in a case of a layered sheet using such a member sheet having low tensile strength, cracks are likely to occur at the time of bending, and it is difficult to eliminate the cracks within the scope of the related art.

The “main component” refers to a component that occupies the largest mass ratio among resin components constituting the member sheet, and specifically, the component occupies 50% by mass or more of the member sheet or a resin composition forming the member sheet, more preferably 55% by mass or more, and still more preferably 60% by mass or more.

In the present adhesive sheet I and the present adhesive layer I, when the creep compliance value measured when a stress of 3,000 Pa is applied is set to the minimum creep compliance J(t)min (MPa⁻¹), and the maximum creep compliance value measured during a period in which the stress of 3,000 Pa continues to be applied until 3757 seconds after the minimum creep compliance J(t)min is measured is set to the maximum creep compliance J(t)max (MPa⁻¹), if the creep compliance fluctuation value Δ log J(t) calculated based on the difference between the minimum creep compliance J(t)min and the maximum creep compliance J(t)max is less than 1.0, even when the present adhesive sheet I and the present adhesive layer I are attached to the member sheet and folded at a high temperature, it is possible to obtain the present adhesive sheet I and the present adhesive layer I which are not influenced by being placed in a bent state and are excellent in restoration property.

From this viewpoint, the creep compliance fluctuation value Δ log J(t) is preferably less than 1.0, more preferably 0.9 or less, and still more preferably 0.8 or less.

<<Present Adhesive Sheet II>>

An adhesive sheet according to an example of the embodiment of the present invention (hereinafter, may be referred to as the “present adhesive sheet II”) satisfies the following requirements (3) and (4).

(3) A maximum value (tan δ (max)) of a loss elastic modulus in a temperature range of −60° C. to 25° C. obtained by dynamic viscoelasticity measurement in a shear mode at a frequency of 1 Hz is 1.5 or more.

(4) When a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

<<Present Flexible Image Display Device Member II>>

A flexible image display device member according to an example of the embodiment of the present invention (hereinafter, may be referred to as the “present flexible image display device member II”) has a configuration in which two flexible members are bonded together via an adhesive layer, and the adhesive layer (hereinafter, may be referred to as the “present adhesive layer II”) satisfies the following requirements (3) and (4).

(3) A maximum value (tan δ (max)) of a loss elastic modulus in a temperature range of −60° C. to 25° C. obtained by dynamic viscoelasticity measurement in a shear mode at a frequency of 1 Hz is 1.5 or more.

(4) When a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

<<Present Adhesive Sheet II and Present Adhesive Layer II>>

First, the present adhesive sheet II and the present adhesive layer II will be described.

<Storage Shear Modulus and Loss Tangent>

In the present adhesive sheet II and the present adhesive layer II, the maximum value (tan δ (max)) of the loss elastic modulus in the temperature range of −60° C. to 25° C. obtained by the dynamic viscoelasticity measurement in the shear mode at a frequency of 1 Hz is preferably 1.5 or more, more preferably 1.6 or more, and still more preferably L7 or more.

On the other hand, an upper limit value of the maximum value (tan δ (max)) is preferably 4.0 or less from the viewpoint of restoration property maintenance from folding.

By setting the tan δ (max) in the above range, for example, when the present adhesive sheet II or the present adhesive layer II is attached to a member sheet to form a layered sheet or a flexible image display device member, an interlayer stress at the time of bending the layered sheet and the flexible image display device member can be reduced at a high temperature from a normal temperature, and even when an impact due to contact or pressurization is received, the impact is absorbed by the adhesive sheet or the adhesive layer, so that damage to the member sheet and the flexible image display device member due to the impact can be prevented.

As a method for setting the tan δ (max) in the above range, when the present adhesive sheet II or the present adhesive layer II is produced, types and mass average molecular weights of resins constituting main components of the present adhesive sheet II or the present adhesive layer II, and blending of resins other than the main components may be adjusted.

However, the present invention is not limited to this method.

Further, in the present adhesive sheet II and the present adhesive layer II, a storage shear modulus at −20° C. (G′ (−20° C.)) obtained by the dynamic viscoelasticity measurement in the shear mode at a frequency of 1 Hz is preferably 1.0 MPa or less, more preferably 0.70 MPa or less, and still more preferably 0.60 MPa or less. On the other hand, a lower limit of the storage shear modulus (G′ (−20° C.)) is preferably 0.05 MPa or more from the viewpoint of shape maintenance on a high-temperature side.

By setting the storage shear modulus (G′ (−20° C.)) of the present adhesive sheet II and the present adhesive layer II to 1.0 MPa or less, the interlayer stress at the time of bending at a low temperature can be reduced, and delamination or cracking of the member sheet or the flexible member can be prevented.

In general, since the adhesive sheet and the adhesive layer have a glass transition temperature (Tg) between a low temperature and a normal temperature, the storage shear modulus (G′ (−20° C.)) is larger than the storage shear modulus (G′ (60° C.)).

However, if the storage shear modulus (G′ (−20° C.)) is 1.0 MPa or less, the member sheet or the flexible member can be prevented from being cracked even when the bending operation is performed at a low temperature.

Further, in the present adhesive sheet II and the present adhesive layer II, a storage shear modulus at 60° C. (G′ (60° C.)) obtained by the dynamic viscoelasticity measurement in the shear mode at a frequency of 1 Hz is preferably 0.005 MPa or more and less than 0.20 MPa, more preferably 0.18 MPa or less, still more preferably 0.15 MPa or less, and even more preferably 0.12 MPa or less.

On the other hand, a lower limit of the storage shear modulus (G′ (60° C.)) is preferably 0.004 MPa or more from the viewpoint of shape maintenance.

By setting the storage shear modulus (G′ (60° C.)) in the above range, for example, when the present adhesive sheet II or the present adhesive layer II is attached to a member sheet to form a layered sheet or a flexible image display device member, an interlayer stress at the time of bending the layered sheet or the flexible image display device member at a high temperature from a normal temperature can be reduced, and delamination or cracking of the member sheet or the flexible member can be prevented.

The loss tangent at 60° C. (tan δ (60° C.)) of the present adhesive sheet II and the present adhesive layer II in shear measurement at a frequency of 1 Hz is preferably 0.60 or less, more preferably 0.55 or less, and still more preferably 0.50 or less. On the other hand, a lower limit of the loss tangent (tan δ (60° C.)) is preferably 0.20 or more from the viewpoint of adhesive strength maintenance.

By setting the loss tangent (tan δ (60° C.)) in the above range, flows of the present adhesive sheet I and the present adhesive layer II can be prevented, and for example, when the present adhesive sheet II or the present adhesive layer II is attached to a member sheet to form a layered sheet or a flexible image display device member, the restoration property can be made good when the layered sheet or the flexible image display device member is unbent from a bent state.

Even when the storage shear modulus (G′ (60° C.)) of the present adhesive sheet II and the present adhesive layer II is less than 0.20 MPa, when the loss tangent (tan δ (60° C.)) is large, creep deformation occurs in the present adhesive sheet II or the present adhesive layer II during high-temperature bending.

However, by setting the loss tangent (tan δ (60° C.)) to 0.60 or less, the creep deformation can be prevented, and the restoration property when the layered sheet or the flexible image display device member is unbent from a bent state can also be made good.

<Maximum Point of Loss Tangent (tan δ) and Glass Transition Temperature (Tg)>

The maximum point of the loss tangent of the present adhesive sheet II and the present adhesive layer II obtained by the dynamic viscoelasticity measurement in the shear mode at a frequency of 1 Hz is preferably at −25° C. or lower.

The maximum point of the loss tangent (tan δ) can be interpreted as the glass transition temperature (Tg), and by setting the glass transition temperature (Tg) in the above range, the storage shear modulus (G′ (−20° C.)) of the present adhesive sheet II and the present adhesive layer II is easily adjusted to 1.0 MPa or less.

The “glass transition temperature” refers to a temperature at which a main dispersion peak of the loss tangent (tan δ) appears. Therefore, when the maximum point of the loss tangent (tan δ) obtained by the dynamic viscoelasticity measurement in the shear mode at a frequency of 1 Hz is observed only at one point, in other words, when a tan δ curve exhibits a unimodal shape, it can be considered that the glass transition temperature (Tg) is single.

The “maximum point” of the loss tangent (tan δ) means a point having a peak value in the tan δ curve, that is, a maximum value in a predetermined range or the entire range among inflection points at which the value changes from positive (+) to negative (−) at the time of differentiation.

The elastic modulus (storage elastic modulus) G′, the viscosity (loss elastic modulus) G″, and tan δ=G″/G′ at various temperatures can be measured by using a strain rheometer.

The storage shear modulus (G′) and the loss tangent (tan δ) can be adjusted to the above ranges by adjusting types, mass average molecular weights, and the like of resins constituting the present adhesive sheet II and the present adhesive layer II (for example, an acrylic (co)polymer and a curable compound described later), or further adjusting the gel fraction of the adhesive sheet and the adhesive layer. However, the present invention is not limited to these methods.

<Creep Compliance>

In the present adhesive sheet II and the present adhesive layer II, when a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is preferably less than 1.0.

In order to reduce the creep compliance fluctuation value Δ log J(t), in a crosslinked structure of the present adhesive sheet II and the present adhesive layer II, it is preferable to adopt a method for increasing the gel fraction by increasing the number of crosslinking points or forming a molecular chain entangled structure with an increased molecular weight between the crosslinking points by forming a crosslinked structure having a long chain structure.

The creep compliance fluctuation value Δ log J(t) can also be adjusted by adjusting types, mass average molecular weights, and the like of polymers forming the present adhesive sheet II and the present adhesive layer II.

However, the method for adjusting the creep compliance fluctuation value Δ log J(t) is not limited to these methods.

In recent years, due to a demand for weight reduction of an image display device, the member sheet to be used tends to be thin, and it is important to reduce a stress on the member sheet.

Here, examples of the member sheet included in the image display device and to be attached to the present adhesive sheet II and the present adhesive layer II include a sheet containing a cycloolefin resin, a triacetyl cellulose resin, a polymethyl methacrylate resin, an epoxy resin, and a polyimide resin as a main component.

Among them, tensile strength at 25° C. of a sheet containing a cycloolefin resin as a main component is as low as 40 MPa to 60 MPa at a thickness of 100 μm, and in a case of a layered sheet using such a member sheet having low tensile strength, cracks are likely to occur at the time of bending, and it is difficult to eliminate the cracks within the scope of the related art.

The “main component” refers to a component that occupies the largest mass ratio among resin components constituting the member sheet, and specifically, the component occupies 50% by mass or more of the member sheet or a resin composition forming the member sheet, more preferably 55% by mass or more, and still more preferably 60% by mass or more.

In the present adhesive sheet II and the present adhesive layer II, when the creep compliance value measured when a stress of 3,000 Pa is applied is set to the minimum creep compliance J(t)min (MPa⁻¹), and the maximum creep compliance value measured during a period in which the stress of 3,000 Pa continues to be applied until 3757 seconds after the minimum creep compliance J(t)min is measured is set to the maximum creep compliance J(t)max (MPa⁻¹), if the creep compliance fluctuation value Δ log J(t) calculated based on the difference between the minimum creep compliance J(t)min and the maximum creep compliance J(t)max is less than 1.0, even when the present adhesive sheet II and the present adhesive layer II are attached to the member sheet and folded at a high temperature, it is possible to obtain the present adhesive sheet II and the present adhesive layer II which are not influenced by being placed in a bent state and are excellent in restoration property.

From this viewpoint, the creep compliance fluctuation value Δ log J(t) is preferably less than 1.0, more preferably 0.9 or less, and still more preferably 0.8 or less.

<Metal Component Amount>

In the present adhesive sheet II and the present adhesive layer II, a content of a metal element (a total content in a case of containing two or more kinds of metal elements) is preferably less than 1000 ppm, more preferably 800 ppm or less, still more preferably 600 ppm or less, and particularly preferably 400 ppm or less.

By setting the total content of the metal elements contained in the present adhesive sheet II and the present adhesive layer II in the above range, corrosion of copper or silver can be more effectively prevented.

The above metal element is preferably one or more selected from the group consisting of Fe, Zn, Zr, Bi, Al, and Sn from the viewpoints that the metal element is a metal component contained in an adhesive and is easily corroded and cured.

With respect to the content of the metal component in an adhesive resin, metal components in the adhesive sheet and the adhesive layer can be quantified by a high-frequency inductively coupled plasma emission spectroscopy method and an absolute calibration curve method by using a high-frequency inductively coupled plasma emission spectrophotometer.

At this time, a total amount of elements detected at a quantification lower limit (50 ppm) or more can be used.

In the present adhesive sheet II and the present adhesive layer II, examples of a method for adjusting the content of the metal element to the above range include a method for adjusting the content of these elements by adjusting a production method of a (meth)acryloyl group-containing component or adjusting conditions by washing the (meth)acryloyl group-containing component.

However, the present invention is not limited to these methods.

<Gel Fraction>

The gel fraction of the present adhesive sheets I and II and the present adhesive layers I and II is preferably 70% or more, more preferably 75% or more, and still more preferably 80% or more.

By setting the gel fraction of the present adhesive sheets I and II and the present adhesive layers I and II to 70% or more, the shape can be sufficiently maintained.

<Total Light Transmittance and Haze>

The total light transmittance of the present adhesive sheets I and II and the present adhesive layers I and II is preferably 85% or more, more preferably 88% or more, and still more preferably 90% or more.

The haze of the present adhesive sheets I and II and the present adhesive layers I and II is preferably 1.0% or less, more preferably 0.8% or less, and particularly preferably 0.5% or less.

By being set to a haze of 1.0% or less, the present adhesive sheet I and the present adhesive layer I, and the present adhesive sheet II and the present adhesive layer II can be used for an image display device.

In order to set the haze of the present adhesive sheets I and II and the adhesive layers I and II in the above range, it is preferable that the present adhesive sheet I and the present adhesive layer I, and the present adhesive sheet II and the present adhesive layer II do not contain particles such as organic particles.

<Thickness>

The thickness of the present adhesive sheets I and II and the present adhesive layers I and II is not particularly limited, and when the thickness is 5 μm or more, a handling property is good, and when the thickness is 1,000 μm or less, the thickness of a layered body can be reduced.

Therefore, the thickness of the present adhesive sheets I and II and the present adhesive layers I and II is preferably 5 μm or more, more preferably 8 μm or more, and particularly preferably 10 μm or more.

On the other hand, an upper limit is preferably 1,000 μm or less, more preferably 500 μm or less, and particularly preferably 250 μm or less.

The present adhesive layers I and II are not limited in form, and may be formed by bonding a sheet-shaped adhesive product formed into a sheet shape in advance to the present flexible image display device member I or II, or may be formed by directly forming an adhesive layer on the present flexible image display device member I or II.

<Acrylic (Co)Polymer>

The present adhesive sheets I and II and the present adhesive layers I and II are each preferably formed by curing a resin composition containing an acrylic (co)polymer having a (meth)acrylate as a monomer component and a curable composition described later.

By containing the acrylic (co)polymer as a component before curing, adhesion strength and cohesive strength of the present adhesive sheets I and II and the present adhesive layers I and II can be increased.

The present adhesive sheets I and II and the present adhesive layers I and II can also be formed by curing a resin composition containing a mixture of monomer components constituting the acrylic (co)polymer or a partial polymer thereof, and a curable resin described later.

Examples of the (meth)acrylate include a monofunctional (meth)acrylate (a1) having one (meth)acryloyl group, and a polyfunctional (meth)acrylate (a2) having two or more (meth)acryloyl groups, among which the monofunctional (meth)acrylate (a1) is preferable.

In the present invention, the “(meth)acrylic” means to include acrylic or methacrylic, the “(meth)acryloyl” means to include acryloyl or methacryloyl, and the “(meth)acrylate” means to include acrylate or methacrylate.

The “(co)polymer” means to include a homopolymer and a copolymer.

Hereinafter, the monomer components forming the acrylic (co)polymer will be described in detail.

(Monofunctional (Meth)Acrylate (a1))

Examples of the monofunctional acrylate which is a constituent monomer of the acrylic (co)polymer include (meth)acrylates having a functional group such as a carboxy group-containing (meth)acrylate, a hydroxy group-containing (meth)acrylate, an epoxy group-containing (meth)acrylate, an amino group-containing (meth)acrylate, and an amide group-containing (meth)acrylate, in addition to an alkyl (meth)acrylate.

In the present adhesive sheets I and II and the present adhesive layers I and II, from the viewpoint of adjusting the glass transition temperatures of the present adhesive sheets I and II and the present adhesive layers I and II, it is preferable to contain an alkyl (meth)acrylate as the monofunctional acrylate which is the constituent monomer of the acrylic (co)polymer.

As the alkyl (meth)acrylate, either a linear or branched alkyl (meth)acrylate can be used. Examples thereof include n-butyl (meth)acrylate, isobutyl (meth)acrylate, sec-butyl (meth)acrylate, t-butyl (meth)acrylate, pentyl (meth)acrylate, isopentyl (meth)acrylate, neopentyl (meth)acrylate, hexyl (meth)acrylate, cyclohexyl (meth)acrylate, heptyl (meth)acrylate, 2-ethylhexyl (meth)acrylate, n-octyl (meth)acrylate, isooctyl (meth)acrylate, nonyl (meth)acrylate, isononyl (meth)acrylate, t-butylcyclohexyl (meth)acrylate, decyl (meth)acrylate, isodecyl (meth)acrylate, undecyl (meth)acrylate, lauryl (meth)acrylate, tridecyl (meth)acrylate, tetradecyl (meth)acrylate, cetyl (meth)acrylate, stearyl (meth)acrylate, isostearyl (meth)acrylate, isobornyl (meth)acrylate, 3,5,5-trimethylcyclohexane (meth)acrylate, dicyclopentayl (meth)acrylate, dicyclopentenyl (meth)acrylate, and dicyclopentenyloxyethyl (meth)acrylate. These may be used alone or in combination of two or more thereof.

Among the alkyl (meth)acrylates, from the viewpoint of adjusting the viscoelasticity of the present adhesive sheets I and II in the above range, the monofunctional (meth)acrylate (a1) is preferably an alkyl (meth)acrylate having an alkyl group having 4 to 20 carbon atoms, and more preferably an alkyl (meth)acrylate having an alkyl group having 4 to 18 carbon atoms.

When the number of carbon atoms in the alkyl of the monofunctional (meth)acrylate (a1) is in the range of 4 to 20, the viscoelasticity of the present adhesive sheets I and II is easily adjusted to the above range. The alkyl (meth)acrylate having an alkyl group which is a branched structure is particularly preferable since the alkyl (meth)acrylate has no crystallinity and has a low glass transition temperature even when the number of the carbon atoms is large.

(Polyfunctional (Meth)Acrylate (a2))

Examples of the constituent monomer of the acrylic (co)polymer may include a polyfunctional (meth)acrylate having a plurality of (meth)acrylate groups, in addition to the monofunctional (meth)acrylate (a1).

The polyfunctional (meth)acrylate (a2) is not particularly limited, and is preferably a polyfunctional urethane (meth)acrylate from the viewpoint of easily adjusting the storage shear modulus at 60° C. (G′ (60° C.)) of the present adhesive sheets I and II or the present adhesive layers I and II to be less than 0.20 MPa.

In order to adjust the creep compliance fluctuation value Δ log J(t) to be less than 1.0, it is necessary to form a crosslinked network.

By selecting the polyfunctional urethane (meth)acrylate as the monomer component in addition to the alkyl (meth)acrylate described above, it is easy to form an appropriate network.

Therefore, it is preferable to use, as the acrylic (co)polymer, a urethane acrylic (co)polymer containing the polyfunctional urethane (meth)acrylate as the monomer component.

In particular, from the viewpoints of not excessively increasing a crosslinking density and keep the storage shear modulus (G′ (60° C.)) less than 0.20 MPa, the polyfunctional (meth)acrylate (a2) is more preferably a bifunctional to trifunctional urethane (meth)acrylate having 2 to 3 (meth)acrylate groups, and particularly preferably a bifunctional urethane (meth)acrylate.

A type of the polyfunctional urethane (meth)acrylate is not particularly limited, and is preferably a polyfunctional urethane (meth)acrylate formed of a reaction product of a polyol compound having two or more hydroxy groups in a molecule, a compound having two or more isocyanate groups in a molecule, and a (meth)acrylate having at least one hydroxy group in a molecule.

Examples of the polyol compound having two or more hydroxy groups in a molecule include a polyether polyol, a polyester polyol, a caprolactone diol, a bisphenol polyol, a polyisoprene polyol, a hydrogenated polyisoprene polyol, a polybutadiene polyol, a hydrogenated polybutadiene polyol, a castor oil polyol, and a polycarbonate diol.

Among them, a polycarbonate diol, a polybutadiene polyol, and a hydrogenated polybutadiene polyol are preferable because of having excellent transparency and durability, and a polycarbonate diol and a hydrogenated polybutadiene polyol are particularly preferable from the viewpoint that white turbidity is not caused even under a high temperature and high humidity condition. These may be used alone or in combination of two or more thereof.

Examples of the compound having two or more isocyanate groups in a molecule include an aromatic polyisocyanate, an alicyclic polyisocyanate, and an aliphatic polyisocyanate. Among them, an aliphatic polyisocyanate and an alicyclic polyisocyanate are preferable from the viewpoint of obtaining a flexible cured product. These may be used alone or in combination of two or more thereof.

Examples of the aromatic polyisocyanate include 2,4-tolylene diisocyanate, 2,6-tolylene diisocyanate, 1,3-xylylene diisocyanate, 1,4-xylylene diisocyanate, tetramethylxylylene diisocyanate, diphenylmethane diisocyanate, naphthalene-1,5-diisocyanate, and triphenylmethane triisocyanate.

Examples of the alicyclic polyisocyanate include isophorone diisocyanate, bis(4-isocyanatocyclohexyl) methane, 1,3-bis(isocyanatomethyl) cyclohexane, 1,4-bis(isocyanatomethyl) cyclohexane, norbornane diisocyanate, and bicycloheptane triisocyanate.

Examples of the aliphatic polyisocyanate include hexamethylene diisocyanate, 1,3,6-hexamethylene triisocyanate, and 1,6,11-undecane triisocyanate.

Among them, diisocyanates such as isophorone diisocyanate and hexamethylene diisocyanate are preferable since a cured product having no white turbidity in an adhesion layer is obtained when placed under a high temperature and a high humidity.

Examples of the (meth)acrylate having at least one hydroxy group in a molecule include mono(meth)acrylates of dihydric alcohols such as ethylene glycol, propylene glycol, 1,3-propanediol, 1,3-butanediol, 1,4-butanediol, and polyethylene glycol, and mono(meth)acrylates or di(meth)acrylates of trihydric alcohols such as trimethylolethane, trimethylolpropane, and glycerin. These may be used alone or in combination of two or more thereof.

A method for synthesizing the polyfunctional urethane (meth)acrylate is not particularly limited, and a known method can be used. For example, a urethane prepolymer is obtained by reacting the polyol compound having two or more hydroxy groups in a molecule with an isocyanate compound having two or more isocyanate groups in a molecule in a diluent (for example, methyl ethyl ketone or methoxyphenol) at a molar ratio (polyol compound:isocyanate compound) of preferably 3:1 to 1:3, and more preferably 2:1 to 1:2. The polyfunctional urethane (meth)acrylate can be obtained by reacting the isocyanate group remaining in the obtained urethane prepolymer with the (meth)acrylate containing at least one hydroxy group in a molecule in a sufficient amount to react with the isocyanate group.

Examples of a catalyst to be used at this time include lead oleate, tetrabutyltin, antimony trichloride, triphenyl aluminum, trioctyl aluminum, dibutyltin dilaurate, copper naphthenate, zinc naphthenate, zinc octylate, zinc octanate, zirconium naphthenate, cobalt naphthenate, tetra-n-butyl-1,3-diacetyloxydistanoxane, triethylamine, 1,4-diaza[2,2,2]bicyclooctane, and N-ethylmorpholine.

Examples of the acrylic (co)polymer include an acrylic (co)polymer containing a urethane (meth)acrylate as the monomer component, and among them, an acrylic (co)polymer containing a polyfunctional urethane (meth)acrylate as the monomer component is preferable.

(Other Monomer Components)

The present adhesive sheets I and II can contain a (meth)acrylate component other than those described above as the monomer component of the acrylic (co)polymer.

For example, in order to improve adhesiveness with the member sheet or the flexible member, it is preferable to contain a monomer having a polar functional group.

Examples of the polar functional group contained in the monomer include a hydroxy group, a thiol group, a carboxy group, a carbonyl group, an ester group, an amino group, an amide group, a glycidyl group, and a silanol group. Among them, a hydroxy group, an amino group, an amide group, a carbonyl group, an ester group, a glycidyl group, and a silanol group are preferable as the polar functional group that improves the adhesiveness with the member and does not easily corrode a peripheral member. Among them, a hydroxy group, an amino group, an amide group, and a glycidyl group are preferable because of having a particularly high effect to improve the adhesiveness.

Examples of the monomer containing such a polar functional group include 4-hydroxybutyl acrylate glycidyl ether, 4-hydroxybutyl acrylate, diethyl acrylamide, hydroxyethyl acrylamide, acryloyl morpholine, and 4-t-butylcyclohexyl acrylate. Among them, 4-hydroxybutyl acrylate, diethyl acrylamide, hydroxyethyl acrylamide, and acryloyl morphine are particularly preferable from the viewpoints of cost and adhesiveness.

In addition to the above monofunctional monomer, a bifunctional or higher functional acrylate may be contained.

<Curable Compound>

The curable compound is a compound having a property of being cured by heat or light irradiation. In the present adhesive sheets I and II and the present adhesive layers I and II, it is preferable that the curable compound forms a crosslinked structure with the acrylic (co)polymer.

The expression “forms a crosslinked structure” includes not only a case where polymer chains are crosslinked via chemical bonds, but also a case where polymer chains are (pseudo) crosslinked by hydrogen bonds within or between the polymer chains, and non-covalent bonds due to an electrostatic interaction and an interaction of Van Der Waals forces.

The curable compound is preferably a compound having an ethylenically unsaturated group in a molecule from the viewpoint of forming the crosslinked structure with the acrylic (co)polymer by curing.

In particular, the curable compound is preferably a (meth)acrylate, and particularly preferably a monofunctional (meth)acrylate. Examples thereof include a urethane (meth)acrylate.

Here, the monofunctional (meth)acrylate refers to a (meth)acrylate having one (meth)acryloyl group.

The curable compound preferably has a glass transition temperature of a homopolymer obtained by homopolymerization with the curable compound of −40° C. or lower, and more preferably −45° C. or lower.

Since the curable compound has a glass transition temperature in such a range, the glass transition temperature of the acrylic (co)polymer can be set relatively high.

Therefore, the present adhesive sheets I and II and the present adhesive layers I and II can exert particularly excellent effects of imparting flexibility against buckling at the time of bending deformation and having bending resistance while ensuring the adhesion.

Among them, the curable compound is preferably a (meth)acrylate having a glycol skeleton. The (meth)acrylate having a glycol skeleton easily has a low glass transition temperature after curing, and easily imparts flexibility and the like by adjusting a molecular weight of the skeleton component.

Examples of the glycol skeleton include an ethylene glycol skeleton, a propylene glycol skeleton, a diethylene glycol skeleton, a butanediol skeleton, a hexanediol skeleton, a 1,4-cyclohexanedimethanol skeleton, a glycolic acid skeleton, and a polyglycol skeleton. Among them, a polyethylene glycol skeleton and/or a polypropylene glycol skeleton are more preferable.

Further, the curable compound is preferably a (meth)acrylate having a mass average molecular weight (MW) of 5,000 or more, more preferably 7,000 or more, and still more preferably 9,000 or more.

If the curable compound is such a (meth)acrylate, the curable compound can be a curable compound having a low glass transition temperature due to a skeleton in which a long linear structure is bonded, and good flexibility can be imparted.

In particular, a urethane (meth)acrylate having a glycol skeleton having a mass average molecular weight of 5,000 or more, more preferably 7,000 or more, and still more preferably 9,000 or more is preferable. By using such a urethane (meth)acrylate, good wettability to an adherend can also be imparted.

The curable compound is preferably contained in a ratio of more than 15 parts by mass and less than 75 parts by mass with respect to 100 parts by mass of the (meth)acrylic (co)polymer. When the curable compound is contained in such a ratio, it is possible to have both the adhesive strength and the bending resistance in a well-balanced manner.

From such a viewpoint, the curable compound is preferably contained in a ratio of more than 15 parts by mass and less than 75 parts by mass, more preferably 20 parts by mass or more or 70 parts by mass or less, and still more preferably in a ratio of 30 parts by mass or more or 65 parts by mass or less, with respect to 100 parts by mass of the (meth)acrylic (co)polymer.

Two or more kinds of curable compounds may be used in combination.

<Radical Initiator>

Preferable examples of a radical initiator used to cure the curable compound to obtain the present adhesive sheet I or II or the present adhesive layer I or II include a compound that generates an active radical species by irradiation with light such as ultraviolet rays or visible light, more specifically, light having a wavelength of 200 nm to 780 nm.

As the radical initiator, either a cleavage type initiator or a hydrogen abstraction type initiator can be used. It is preferable to use the hydrogen abstraction type initiator since a hydrogen abstraction reaction is also caused by the acrylic (co)polymer, and both the curable compound and the acrylic (co)polymer are incorporated into the crosslinked structure to form a crosslinked structure having many crosslinking points.

In addition, it is preferable to use the hydrogen abstraction type initiator from the viewpoint that the hydrogen abstraction type initiator can serve as a starting point of a photoreaction at the time of post-curing when a sheet is used as a so-called post-curing (post-cure) type, which will be described later, since the hydrogen abstraction type initiator can function as a repeated active species with light irradiation again even after being used in a photocuring reaction once.

Examples of the hydrogen abstraction type initiator include benzophenone, 4-methyl-benzophenone, 2,4,6-trimethylbenzophenone, 4-phenylbenzophenone, 3,3′-dimethyl-4-methoxybenzophenone, 4-(meth)acryloyloxybenzophenone, methyl 2-benzoylbenzoate, methyl benzoylformate, bis(2-phenyl-2-oxoacetic acid) oxybisethylene, acryloyl-1,4,7,10,13-pentaoxatridecyl) benzophenone, thioxanthone, 2-chlorothioxanthone, 3-methylthioxanthone, 2,4-dimethylthioxanthone, 2-methylanthraquinone, 2-ethylanthraquinone, 2-tert-butylanthraquinone, 2-aminoanthraquinone, and derivatives thereof.

A lower limit of a content of the radical initiator is preferably 0.01 parts by mass or more, more preferably 0.03 parts by mass or more, and still more preferably 0.05 parts by mass or more, with respect to 100 parts by mass of the (meth)acrylic (co)polymer.

An upper limit thereof is preferably 5 parts by mass or less, more preferably 3 parts by mass or less, and still more preferably 2 parts by mass or less, with respect to 100 parts by mass of the (meth)acrylic (co)polymer.

<Other Components>

The present adhesive sheets I and II and the present adhesive layers I and II can contain components other than the acrylic (co)polymer and the curable compound (also referred to as “other components”). The other components are not particularly limited, and the present adhesive sheets I and II and the present adhesive layers I and II may contain other monomer components and polymer components.

The present adhesive sheets I and II and the present adhesive layers I and II may contain a rust inhibitor as the other components.

As types of the rust inhibitor, triazoles and benzotriazoles are particularly preferable, and corrosion of a transparent electrode on a touch panel can be prevented.

An addition amount is preferably 0.01% by mass to 5% by mass, and more preferably 0.1% by mass or more or 3% by mass or less, with respect to a total amount of the present adhesive sheets I and II and the present adhesive layers I and II.

The present adhesive sheets I and II and the present adhesive layers I and II may contain a silane coupling agent as the other components.

As types of the silane coupling agent, those having a glycidyl group, or those having a (meth)acryl group and a vinyl group are particularly preferable.

By containing these, when a layered body is formed by using the present adhesive sheets I and II and the present adhesive layers I and II, the adhesiveness with the member sheet or the flexible member is improved, and a foaming phenomenon in a wet heat environment can be prevented.

A content of the silane coupling agent is preferably 0.01% by mass to 3% by mass, and more preferably 0.1% by mass or more or 1% by mass or less, with respect to the total amount of the present adhesive sheets I and II and the present adhesive layers I and II. Depending on the adherend, the silane coupling agent may exhibit an effect even with a content of 0.01% by mass.

On the other hand, by adjusting the content to 3% by mass or less, foaming caused by dealcoholization can be prevented.

The present adhesive sheets I and II and the present adhesive layers I and II may contain, as other components, a curing accelerator, a filler, a coupling agent, an ultraviolet absorber, an ultraviolet stabilizer, an antioxidant, a stabilizer, a pigment, or a combination thereof.

An amount of these additives is typically preferably selected so as not to adversely influence the curing of the adhesive sheet and the adhesive layer, or so as not to adversely influence physical properties of the adhesive sheet and the adhesive layer.

<Preferable Application of Present Adhesive Sheets I and II>

The present adhesive sheets I and II are preferably used for bonding a member constituting a display member (also referred to as a “display member”), in particular, for bonding a flexible member for display used for producing a display, and particularly preferably used as an adhesive component for flexible display used for producing a flexible display.

Components same as those described later can be used for the flexible member.

<Constituent Element of Present Flexible Image Display Device Members I and II>

Next, elements among constituent elements of the present flexible image display device members I and II other than the present adhesive layers I and II will be described.

(Flexible Member)

Examples of the flexible member constituting the present flexible image display device members I and II include flexible displays such as an organic electroluminescent (EL) display, and flexible members for display such as a cover lens (cover film), a polarizing plate, a polarizer, a retardation film, a barrier film, a viewing angle compensation film, a brightness enhancement film, a contrast enhancement film, a diffusion film, a semi-transmissive reflective film, an electrode film, a transparent conductive film, a metal mesh film, and a touch sensor film. One or two of these may be used in combination. Examples thereof include a combination of a flexible display and another flexible member, and a combination of a cover lens and another flexible member.

The flexible member means a bendable member, in particular, a member that can be repeatedly bent. In particular, preferred is a member that can be fixed to a curved shape having a bending radius of 25 mm or more, particularly a member that can withstand repeated bending actions at a bending radius of less than 25 mm, and more preferably less than 3 mm.

In the above-described configuration, examples of the main component of the flexible member include a cycloolefin resin, a triacetyl cellulose resin, a polymethyl methacrylate resin, an epoxy resin, and a polyimide resin, and among them, one kind of resin or two or more kinds of resins may be used.

Here, the “main component” refers to a component that occupies the largest mass ratio among the components constituting the flexible member, and specifically occupies 50% by mass or more of the resin composition forming the flexible member, and more preferably 55% by mass or more, and still more preferably 60% by mass or more.

The flexible member may be made of a thin film glass.

In the above-described configuration, in particular, one of the two flexible members, that is, a first flexible member, preferably has tensile strength at 25° C. measured according to ASTM D882 of 10 MPa to 900 MPa, more preferably 15 MPa or more or 800 MPa or less, and still more preferably 20 MPa or more or 700 MPa or less.

The other flexible member, that is, a second member sheet, preferably has tensile strength at 25° C. measured according to ASTM D882 of 10 MPa to 900 MPa, more preferably 15 MPa or more or 800 MPa or less, and still more preferably 20 MPa or more or 700 MPa or less.

Examples of a flexible member having high tensile strength include a polyimide film and a polyester film, and the tensile strength thereof is generally 900 MPa or less.

On the other hand, examples of a flexible member sheet having slightly low tensile strength include a triacetyl cellulose (TAC) film and a cyclic olefin polymer (COP) film, and the tensile strength thereof is 10 MPa or more.

Even when the flexible image display device members I and II have a flexible member made of a material having such slightly low tensile strength, defects such as cracks can be prevented by actions of the present adhesive layer I or II.

<<Present Layered Sheet I>>

A layered sheet (hereinafter, may be referred to as the “present layered sheet I”) according to an example of the embodiment of the present invention includes a member sheet that satisfies a requirement (5) on at least one surface of the present adhesive sheet I or the present adhesive layer I.

(5) Tensile strength at 25° C. measured according to ASTM D882 is 10 MPa to 900 MPa.

The present layered sheet I is preferably a layered sheet having a configuration in which a member sheet (hereinafter, may be referred to as a “first member sheet”), the present adhesive sheet I or the present adhesive layer I, and any member sheet (hereinafter, may be referred to as a “second member sheet”) are layered in this order.

In this case, it is preferable that the second member sheet also satisfies the requirement (5).

The first member sheet and the second member sheet may be the same as or different from each other.

<<Present Layered Sheet II>>

A layered sheet (hereinafter, may be referred to as the “present layered sheet II”) according to an example of the embodiment of the present invention includes a member sheet that satisfies the requirement (5) on at least one surface of the present adhesive sheet II or the present adhesive layer II.

(5) Tensile strength at 25° C. measured according to ASTM D882 is 10 MPa to 900 MPa.

The present layered sheet II is preferably a layered sheet having a configuration in which a member sheet (hereinafter, may be referred to as a “first member sheet”), the present adhesive sheet II or the present adhesive layer II, and any member sheet (hereinafter, may be referred to as a “second member sheet”) are layered in this order.

In this case, it is preferable that the second member sheet also satisfies the requirement (5).

The first member sheet and the second member sheet may be the same as or different from each other.

The thickness of the present layered sheets I and II is not particularly limited. For example, as an example of a case where the present layered sheets I and II are used in the image display device, the present layered sheets I and II are sheet-shaped, and if the thickness thereof is 0.01 mm or more, the handleability is good, and if the thickness thereof is 1.0 mm or less, the thickness of the layered body can be reduced.

Therefore, the thickness of the present layered sheets I and II is preferably 0.01 mm or more, more preferably 0.03 mm or more, and particularly preferably 0.05 mm or more.

On the other hand, an upper limit is preferably 1.0 mm or less, more preferably 0.7 mm or less, and particularly preferably 0.5 mm or less.

The present layered sheet I or II can be produced by bonding the present adhesive sheet I or the present adhesive layer I, or the present adhesive sheet II or the present adhesive layer II to the first member sheet and the second member sheet. However, the present invention is not limited to such a production method.

<Member Sheet>

Although depending on the configuration of the flexible image display device and the positions of the present adhesive sheet I or II or the present adhesive layer I or II, examples of the first member sheet and the second member sheet include a cover lens, a polarizing plate, a retardation film, a barrier film, a touch sensor film, and a light emitting element.

In particular, in consideration of the configuration of an image display device, it is preferable that the first member sheet has a touch input function. When the present adhesive sheet I or II or the present adhesive layer I or II has the second member sheet described above, the second member sheet may also have a touch input function.

Examples of a main component of the member sheet include a cycloolefin resin, a triacetyl cellulose resin, a polymethyl methacrylate resin, an epoxy resin, and a polyimide resin, and among them, one kind of resin or two or more kinds of resins may be used.

The “main component” refers to a component that occupies the largest mass ratio among components constituting the member sheet, and specifically, the component occupies 50% by mass or more of the member sheet or a resin composition forming the member sheet, more preferably 55% by mass or more, and still more preferably 60% by mass or more.

The member sheet may be made of a thin film glass. Here, the thin film glass refers to a glass having a thickness of the member sheet described above.

The first member sheet preferably has tensile strength at 25° C. measured according to ASTM D882 of 10 MPa to 900 MPa, more preferably 15 MPa or more or 800 MPa or less, and still more preferably 20 MPa or more or 700 MPa or less.

When the present adhesive sheet I or the present adhesive layer I or the present adhesive sheet II or the present adhesive layer II has the second member sheet described above, the second member sheet preferably has tensile strength at 25° C. measured according to ASTM D882 of 10 MPa to 900 MPa, more preferably 15 MPa or more or 800 MPa or less, and still more preferably 20 MPa or more or 700 MPa or less.

Examples of a member sheet having high tensile strength include a polyimide film and a polyester film, and the tensile strength thereof is generally 900 MPa or less.

On the other hand, examples of a member sheet having slightly low tensile strength include a triacetyl cellulose (TAC) film and a cyclic olefin polymer (COP) film, and the tensile strength thereof is 10 MPa or more.

Even when the present layered sheets I and II have a member sheet made of a material having slightly low tensile strength, defects such as cracks can be prevented by actions of the adhesive sheet.

<<Method for Producing Present Adhesive Sheet I, Present Layered Sheet I, Present Adhesive Sheet II, and Present Layered Sheet II>>

Next, a method for producing the present adhesive sheet I, the present adhesive sheet II, the present layered sheet I, and the present layered sheet II will be described. However, the following description is an example of the method for producing the present adhesive sheets I and II and the present layered sheets I and II, and the present adhesive sheet I, the present adhesive sheet II, the present layered sheet I, and the present layered sheet II are not limited to those produced by such a production method.

In the production of the present adhesive sheets I and II, the present adhesive sheet I or II may be produced by preparing a resin composition for forming the present adhesive sheet I or II, which contains the acrylic (co)polymer, the curable compound, the radical initiator, and other components, molding the resin composition into a sheet shape, crosslinking the curable compound, that is, polymerizing the curable compound for curing, and performing appropriate processing as necessary.

In the production of the present adhesive layers I and II, the present adhesive layer I or II may be formed by preparing a resin composition for forming the present adhesive layer I or II in the same manner as described above, coating the member sheet or the flexible member with the resin composition, and curing the resin composition.

However, the present invention is not limited to this method.

When the resin composition for forming the present adhesive sheet I or II or the present adhesive layer I or II is prepared, the above raw materials may be kneaded by using a temperature-controllable kneader (for example, a single-screw extruder, a twin-screw extruder, a planetary mixer, a twin-screw mixer, or a pressurizing kneader).

When various raw materials are mixed, various additives such as a silane coupling agent and an antioxidant may be blended in advance with a resin and then supplied to the kneader, or all materials may be melted and mixed in advance and then supplied, or a masterbatch in which only the additive is concentrated in a resin in advance may be produced and supplied.

In order to impart curability to the present adhesive sheet I or II or the present adhesive layer I or II, as described above, it is preferable to use the radical initiator to polymerize, in other words, crosslink the resin composition for forming the present adhesive sheet I or II or the present adhesive layer I or II.

At this time, the resin composition for forming the present adhesive sheet I or II or the present adhesive layer I or II may be applied to the first member sheet or the second member sheet and polymerized, or the resin composition for forming the present adhesive sheet I or II or the present adhesive layer I or II may be polymerized and attached.

As a method for molding the resin composition for forming the present adhesive sheet I or II into a sheet shape, known methods, for example, a wet lamination method, a dry lamination method, an extrusion casting method using a T-die, an extrusion lamination method, a calender method, an inflation method, an injection molding method, or a liquid injection curing method can be adopted. Among them, when producing a sheet, a wet lamination method, an extrusion casting method, and an extrusion lamination method are preferable.

When the resin composition for forming the present adhesive sheet I or II or the present adhesive layer I or II contains the radical initiator, the cured product can be produced by irradiation with heat and/or active energy rays and curing.

In particular, the present adhesive sheet I or II or the present adhesive layer I or II can be produced by molding the resin composition for forming the present adhesive sheet I or II or the present adhesive layer I or II into a molded body, for example, a sheet body, and irradiating the molded body with heat and/or active energy rays.

Here, examples of the active energy ray for irradiation include ionizing radiation such as α rays, β rays, γ rays, neutron rays, and electron beams, ultraviolet rays, and visible rays, and among them, ultraviolet rays are preferable from the viewpoint of preventing damage to constituent members of an optical device and controlling a reaction.

Irradiation energy, irradiation times, irradiation methods, and the like of the active energy rays are not particularly limited, and the radical initiator may be activated to polymerize the monomer component.

When a hydrogen abstraction type initiator is used as the radical initiator, a hydrogen abstraction reaction can also be caused by the acrylic (co)polymer, and both a photocurable compound and the acrylic (co)polymer can be incorporated into the crosslinked structure to form a crosslinked structure having many crosslinking points.

Therefore, the present adhesive sheet I or II or the present adhesive layer I or II is preferably cured by using the hydrogen abstraction type initiator.

Another embodiment of the method for producing the present adhesive sheets I and II can be implemented by dissolving the resin composition for forming the present adhesive sheet I or II described later in an appropriate solvent and using various coating methods and the present adhesive sheets can be produced.

When a coating method is used, the present adhesive sheet I or II can also be obtained by thermal curing in addition to the above-described active energy ray irradiation curing.

In the case of coating, the thickness of the adhesive sheet can be adjusted by a coating thickness and a solid content concentration of a coating liquid.

From the viewpoint of preventing blocking and foreign matter adhesion, it is also possible to provide a protective film in which a release layer is layered on at least one surface of the present adhesive sheet I or II or the present adhesive layer I or II.

Embossing or various uneven (such as a cone, a pyramid shape, or a hemispherical shape) processing may be performed as necessary. For the purpose of improving the adhesion to various member sheets, various surface treatments such as a corona treatment, a plasma treatment, and a primer treatment may be performed on the surface.

<<Method for Producing Present Flexible Image Display Device Members I and II>>

A method for producing the present flexible image display device members I and II is not particularly limited, and as described above, the present flexible image display device members I and II may be formed by coating the flexible member with the resin composition for forming the present adhesive layer I or II, or the resin composition may be molded into a sheet shape in advance, and then bonded to the flexible member.

<<Present Image Display Devices I and II>>

By incorporating the present layered sheet I or II, for example, by layering the present layered sheet I or II on another constituent member of the image display device, it is possible to form a flexible image display device provided with the present layered sheet I or II (may be referred to as the “present image display device I” or the “present image display device II”).

The flexible image display device refers to an image display device that does not leave a trace of bending even when repeatedly bent, can quickly recover to a state before the bending when the bending is released, and can display an image without distortion even when bent.

More specifically, the flexible image display device is an image display device made of a member that can have a curved fixed shape having a bending radius of 25 mm or more, in particular, a member that can withstand repeated bending actions at a bending radius of less than 25 mm, and more preferably less than 3 mm.

In particular, the present layered sheet I can be used to produce an image display device excellent in flexibility since delamination or cracking of the layered sheet can be prevented even when the folding operation is performed in a high temperature environment and the restoration property is good.

<<Description of Terms>>

In the present invention, the term “film” includes “sheet”, and the term “sheet” also includes “film”.

When expressed as a “panel” such as an image display panel or a protective panel, the panel includes a plate, a sheet, and a film.

In the present specification, unless otherwise specified, “X to Y” (X and Y are any numbers) includes the meaning of “X or more and Y or less”, and also includes the meaning of “preferably larger than X” or “preferably smaller than Y”.

In addition, unless otherwise specified, “X or more” (X is any number) includes the meaning of “preferably larger than X”, and “Y or less” (Y is any number) includes the meaning of “preferably smaller than Y”.

### Examples

The present invention will be further described with reference to the following Examples. However, the present invention is not limited to the following Examples.

<<First Example Group>>

First, an example related to the flexible image display device member I proposed in the present invention will be described.

<Raw Materials>

First, raw materials of the resin composition prepared in this example will be described in detail.

1. Acrylic (co)polymer
Acrylic copolymer a: an acrylic copolymer (mass average molecular weight: about 700,000) composed of 2-ethylhexyl acrylate, methyl acrylate, ethyl acrylate, 2-hydroxyethyl acrylate, and 4-hydroxyacrylate
Acrylic copolymer b: a urethane acrylic copolymer (mass average molecular weight: about 900,000) obtained by adding 600 ppm of 2-methacryloyloxyethyl isocyanate (“Karenz MOI” manufactured by Showa Denko K. K.) to a copolymer composed of about 85 mol % of butyl acrylate and about 15 mol % of 2-hydroxyl acrylate
Acrylic copolymer c: a commercially available 2-ethylhexyl acrylate copolymer (mass average molecular weight: about 540,000)
Acrylic copolymer d: a commercially available 2-ethylhexyl acrylate copolymer having an acryloyl group in a side chain

2. Curable compound
Urethane acrylate a: a propylene glycol skeleton-containing monofunctional urethane acrylate, PEM-X264 (manufactured by AGC), mass average molecular weight: about 10,000, glass transition temperature: −53° C.
Urethane acrylate b: a bifunctional urethane acrylate (bifunctional urethane acrylate in which hydroxyethyl acrylate is added to the terminal of polypropylene glycol and hexamethylene diisocyanate polymer, mass average molecular weight: about 8,000)

3. Radical initiator
4-methylbenzophenone (hydrogen abstraction type initiator)

4. Silane coupling agent
KBM403 (manufactured by Shin-Etsu Chemical Co., Ltd.)

5. Rust inhibitor
1,2,3-benzotriazole

6. Solvent
Ethyl acetate

TABLE 1

| | | | Example | Example | Example | Example | Example | Example | Comparative | Comparative |
|---|---|---|---|---|---|---|---|---|---|---|
| | | | I-1 | I-2 | I-3 | I-4 | I-5 | I-6 | Example I-1 | Example I-2 |
| Acrylic | a | Part | 100 | 100 | 100 | 100 | 100 | | | |
| (co)polymer | b | Part | | | | | | 100 | | |
| | c | Part | | | | | | | 100 | |
| | d | Part | | | | | | | | 100 |
| Curable | a | Part | 25 | 25 | 25 | 25 | 25 | 6 | 25 | 6 |
| composition | b | Part | | | | | 5 | | | |

| | | | | | | | | | |
|---|---|---|---|---|---|---|---|---|---|
| Photopolymerization | Part | 3 | 3 | 3 | 3 | 3 | 0.5 | 3 | 0.5 |
| initiator | | | | | | | | | |
| Silane coupling agent | Part | 0.3 | 0.3 | 0.3 | 0.3 | 0.3 | 0.3 | 0.3 | 0.3 |
| Rust inhibitor | Part | 0.3 | 0.3 | 0.3 | 0.3 | 0.3 | 0.3 | 0.3 | 0.3 |

| | | | | | | | | |
|---|---|---|---|---|---|---|---|---|
| Solvent | No | No | Ethyl | Ethyl | Ethyl | Ethyl | No | No |
| | | | acetate | acetate | acetate | acetate | | |
| UV irradiation dose (J/cm²) | 3 | 3 | 1 | 1 | 1 | 0.3 | 2 | 1 |

[Preparation I-1 of Adhesive Sheet]

In Examples I-1 and I-2, each of adhesive sheets was obtained as follows.

The raw materials were blended in a mass ratio shown in Table 1 to prepare a resin composition, and the resin composition was developed into a sheet shape such that the thickness of the resin composition was 50 μm on a release film (PET film, manufactured by Mitsubishi Chemical Corporation) having a thickness of 100 μm, which had been subjected to a silicone release treatment.

Next, a release film (PET film, manufactured by Mitsubishi Chemical Corporation) having a thickness of 75 μm, which had been subjected to a silicone release treatment, was layered on the sheet-shaped resin composition to form a layered body, and light irradiation was performed on the resin composition through the release film by using a metal halide lamp irradiation device (UVC-0516S1, lamp UVL-8001M3-N, manufactured by Ushio Inc.) such that a total irradiation amount at a wavelength of 365 nm was 3,000 mJ/cm², thereby obtaining an adhesive sheet layered body in which release films were layered on both front and back sides of a 50 μm adhesive sheet (sample).

[Preparation I-2 of Adhesive Sheet]

In Examples I-3 and I-4, each of adhesive sheets was obtained as follows.

The raw materials were blended in a mass ratio shown in Table 1 to prepare a resin composition containing a solvent, and the resin composition was developed into a sheet shape such that the thickness of the resin composition was 220 μm on the release film having a thickness of 100 μm, which had been subjected to a silicone release treatment.

Next, the sheet-shaped resin composition together with the release film was placed into a dryer heated to 90° C. and held for 10 minutes, and the solvent contained in the resin composition was volatilized.

Further, the release film having a thickness of 75 μm, which had been subjected to a silicone release treatment, was layered on the sheet-shaped resin composition obtained by drying the solvent to form a layered body, and light irradiation was performed on the resin composition through the release film by using a metal halide lamp irradiation device (UVC-0516S1, lamp UVL-8001M3-N, manufactured by Ushio Inc.) such that a total irradiation amount at a wavelength of 365 nm was the value shown in Table 1, thereby obtaining an adhesive sheet layered body in which release films were layered on both front and back sides of an adhesive sheet (sample) having a thickness of 50 μm.

[Preparation I-3 of Adhesive Sheet]

In Examples I-5 and I-6, each of adhesive sheets was obtained as follows.

The raw materials were blended in a mass ratio shown in Table 1 to prepare a resin composition containing a solvent, and the resin composition was developed into a sheet shape such that the thickness of the resin composition was 230 μm on the release film having a thickness of 100 μm, which had been subjected to a silicone release treatment.

Next, the sheet-shaped resin composition together with the release film was placed into a dryer heated to 90° C. and held for 10 minutes, and the solvent contained in the resin composition was volatilized.

Further, the release film having a thickness of 75 μm, which had been subjected to a silicone release treatment, was layered on the sheet-shaped resin composition obtained by drying the solvent to form a layered body, and light irradiation was performed on the resin composition through the release film by using a metal halide lamp irradiation device (UVC-0516S1, lamp UVL-8001M3-N, manufactured by Ushio Inc.) such that a total irradiation amount at a wavelength of 365 nm was the value shown in Table 1, thereby obtaining an adhesive sheet layered body in which release films were layered on both front and back sides of an adhesive sheet (sample) having a thickness of 50 μm.

[Preparation I-4 of Adhesive Sheet]

In Comparative Examples I-1 and I-2, each of adhesive sheets was obtained as follows.

The raw materials were blended in a mass ratio shown in Table 1 to prepare a resin composition, and the resin composition was developed into a sheet shape such that the thickness of the resin composition was 50 μm on a release film (PET film, manufactured by Mitsubishi Chemical Corporation) having a thickness of 100 μm, which had been subjected to a silicone release treatment.

Next, a release film (PET film, manufactured by Mitsubishi Chemical Corporation) having a thickness of 75 μm, which had been subjected to a silicone release treatment, was layered on the sheet-shaped resin composition to form a layered body, and light irradiation was performed on the resin composition through the release film by using a metal halide lamp irradiation device (UVC-0516S1, lamp UVL-8001M3-N, manufactured by Ushio Inc.) such that a total irradiation amount at a wavelength of 365 nm was the value shown in Table 1, thereby obtaining an adhesive sheet layered body in which release films were layered on both front and back sides of a 50 μm adhesive sheet (sample).

[Measurement and Evaluation for Adhesive Sheet]

Measurement and evaluation for the adhesive sheets (samples) obtained in Examples and Comparative Examples were performed as follows.

<Creep Compliance>

The release film was removed from each of the adhesive sheet layered bodies prepared in Examples and Comparative Examples, and a plurality of adhesive sheets (samples) were layered to form a layered body having a thickness of 1.0 mm. A cylinder (height: 1.0 mm) having a diameter of 8 mm was punched out from the obtained layered body of the adhesive layer, and was used as a sample. For the above sample, the creep compliance J(t) (MPa⁻¹) was measured by using a viscoelasticity measurement device (product name “DHR 1” manufactured by T.A. Instruments) and continuously applying a stress of 3,000 Pa under the following conditions.

From a measurement result thereof, a value when the stress of 3,000 Pa was applied was set as a minimum creep compliance J(t)min (MPa⁻¹), and a maximum creep compliance J(t)max (MPa⁻¹) measured until 3757 seconds after the minimum creep compliance J(t)min was measured was derived.

(Measurement Conditions)

Adhesive jig: parallel plate having a diameter of 8 mm Measurement temperature: 25° C.

<Storage Shear Modulus (G′) and Loss Tangent (tan δ)>

The release film was removed from each of the adhesive sheet layered bodies prepared in Examples and Comparative Examples, and a plurality of adhesive sheets (samples) were layered to form a layered body having a thickness of 1.0 mm.

A cylinder (height: 1.0 mm) having a diameter of 8 mm was punched out from the obtained layered body of the adhesive layer, and was used as a sample.

For the above sample, the storage shear modulus (G′) and the loss tangent (tan δ) were measured by using a viscoelasticity measurement device (product name “DHR 1” manufactured by T.A. Instruments) under the following measurement conditions.

From the obtained data, a temperature at which a maximum point of the loss tangent (tan δ) appeared (glass transition temperature (Tg)), a storage shear modulus at −20° C. (G′ (−20° C.)), and a storage shear modulus at 60° C. (G′ (60° C.)) were obtained.

(Measurement Conditions)
Adhesive jig: parallel plate having a diameter of 8 mm
Distortion: 0.1%
Frequency=1 Hz

Measurement temperature: −60° C. to 100° C.

Temperature rising rate: 5° C./min

<Gel Fraction>

The release film was removed from each of the adhesive sheet layered bodies prepared in Examples and Comparative Examples, about 0.1 g of the adhesive sheet (sample) was collected, soaked in ethyl acetate for 24 hours, and dried at 75° C. for 4.5 hours, and then a mass fraction of the remaining gel component was obtained and used as the gel fraction.

<Peel Force>

One of the release films was removed from each of the adhesive sheet layered bodies prepared in Examples and Comparative Examples, and a polyethylene terephthalate film (“Cosmo shine A4300” manufactured by Toyobo Co., Ltd., thickness: 100 μm) as a backing film was roll-bonded to the adhesive sheet (sample) with a hand roller. The obtained adhesive sheet was cut into a strip shape having a width of 10 mm and a length of 150 mm, and the remaining release film was peeled off and the exposed adhesive surface was roll-attached to a transparent polyimide film (main component: transparent polyimide, “C_50” manufactured by KOLON, hereinafter referred to as “CPI film”) which was previously bonded to a stainless steel plate with the hand roller, thereby prepare a layered body consisting of CPI film/adhesive sheet (sample)/backing film, and the layered body was subjected to an autoclave treatment (60° C., gauge pressure: 0.2 MPa, 20 minutes) for finish-bonding to prepare a peel force measurement sample.

The backing film was peeled from the CPI film while pulling the backing film at an angle of 180° at a peeling rate of 60 mm/min, the tensile strength was measured with a load cell, and the 180° peel strength (N/25 mm) of the adhesive sheet with respect to the CPI film before photocuring was measured as the peel strength (60° C.) and shown in Table 2.

[Preparation of Layered Sheet]

The release film of each of the adhesive sheet layered bodies prepared in Examples and Comparative Examples was removed, and a first member sheet and a second member sheet were bonded to both surfaces of the adhesive sheet (sample) with a hand roll to obtain a layered sheet (sample).

At this time, in Examples I-1, 1-3, 1-5, and I-6 and Comparative Examples I-1 and I-2, a CPI film (main component: transparent polyimide, “C_50” manufactured by KOLON, 25° C. tensile strength: 307 MPa) was used as the first member sheet and the second member sheet.

In Examples I-2 and I-4, a COP film (main component: cyclic olefin polymer, “ZF-14” manufactured by Nippon Zeon Corporation, 25° C. tensile strength: 59 MPa) was used as the first member sheet and the second member sheet.

[Evaluation for Layered Sheet]

The layered sheet (sample) prepared as described above by using each of the adhesive sheets (samples) obtained in Examples and Comparative Examples was evaluated as follows.

<Dynamic Bending Property>

The layered sheet (sample) was subjected to a cycle evaluation of U-shaped bending by using a durability system in a thermo-hygrostat and a planar body unloaded U-shaped expansion and contraction tester (manufactured by Yuasa System Co., Ltd.) at a setting of radius of curvature R=3 mm and 60 rpm (1 Hz) with the CPI film or the COP film side as an inner side.

The evaluation was performed at a temperature of −20° C. and a cycle number of 100,000 times. The evaluation was performed according to the following evaluation criteria.

A: None of delamination, breaking, buckling, and flow of a bent portion occurred.

B: any one of delamination, breaking, buckling, and flow of the bent portion occurred.

<Static Bending Property>

The layered sheet (sample) was bent at a radius of curvature R of 3 mm with the CPI film or the COP film side as an inner side, and stored for 24 hours under conditions of 60° C. and 90% RH, and then a jig was released to evaluate the restoration property after 1 hour. The delamination and the restoration property were evaluated according to the following evaluation criteria. Similarly, when the restoration property of only the member sheet (the CPI film and the COP film) was confirmed, an inner angle of the film was 90°.

A: the inner angle of the bent portion was restored to 70° or more and 90° or less.

B: the inner angle of the bent portion was less than 70°, or any one or more of the delamination, breaking, buckling, and flow was observed.

Results obtained by the measurement and evaluation for the adhesive sheet and the layered sheet are shown in Table 2.

TABLE 2

| | | | Example | Example | Example | Example | Example | Example | Comparative | Comparative |
|---|---|---|---|---|---|---|---|---|---|---|
| | | | I-1 | I-2 | I-3 | I-4 | I-5 | I-6 | Example I-1 | Example I-2 |
| Adhesive | Measurement | ΔlogJ(t) creep | 0.8 | 0.8 | 0.9 | 0.9 | 0.7 | 0.7 | 0.9 | 0.7 |
| sheet | | compliance | | | | | | | | |
| | | fluctuation value | | | | | | | | |
| | | G′ (60° C.) [MPa] | 0.01 | 0.01 | 0.01 | 0.01 | 0.03 | 0.02 | 0.04 | 0.004 |
| | | tan δ (60° C.) | 0.43 | 0.43 | 0.48 | 0.48 | 0.36 | 0.40 | 0.69 | 0.17 |
| | | G′ (−20° C.) [MPa] | 0.2 | 0.2 | 0.2 | 0.2 | 0.2 | 0.2 | 0.2 | 0.1 |
| | | Maximum point | −37 | −37 | −38 | −38 | −38 | −40 | −40 | −42 |
| | | (Tg) of tan δ [° C.] | | | | | | | | |
| | | Gel fraction [%] | 73 | 73 | 71 | 71 | 73 | 71 | 62 | 76 |
| | Evaluation | Peel force (60° C.) | 1.9 | 1.9 | 2.3 | 2.3 | 3.5 | 8.8 | 2 | 0.7 |
| | | [N/25 mm] | | | | | | | | |
| Layered | Member sheet | | CPI | COP | CPI | COP | CPI | CPI | CPI | CPI |
| sheet | Evaluation | Static bending | A | A | A | A | A | A | B | B |
| | | property (60° C.) | | | | | | | | |
| | | Dynamic bending | A | A | A | A | A | A | A | B |
| | | property (−20° C.) | | | | | | | | |

In the layered sheets of Examples I-1 to I-6 in which the creep compliance fluctuation value Δ log J(t) was less than 1.0, the storage shear modulus at 60° C. (G′ (60° C.)) was 0.005 MPa or more and less than 0.20 MPa, and the loss tangent at 60° C. (tan δ (60° C.)) was less than 0.60, the delamination did not occur in the static bending test at a high temperature stricter than that in the evaluation at room temperature, which was the evaluation method in PTL 1, and a good restoration property was exhibited.

In particular, in Examples I-1 to I-6 in which the storage shear modulus at −20° C. (G′ (−20° C.)) was 1.0 MPa or less, it was found that excellent performance was also exhibited in the dynamic bending property at a low temperature.

On the other hand, in Comparative Example I-1, the creep compliance fluctuation value Δ log J(t) was controlled to be less than 1.0, but a reaction of the curable component was insufficient, the crosslink density was too low, and Tan δ (60° C.) was more than 0.60, resulting in a poor static bending property.

It was found that in Comparative Example I-2, similarly, the creep compliance fluctuation value Δ log J(t) was controlled to be less than 1.0, but the dynamic bending property and the static bending property were deteriorated since a reaction of the (meth)acryloyl group in the side chain was excessively progressed, the crosslink density was too high, and the G′ (60° C.) was less than 0.005 MPa.

From the above, it was found that the three requirements of the creep compliance fluctuation values Δ log J(t), (G′ (60° C.)) and the loss tangent at 60° C. (tan δ (60° C.)) were technical matters closely related to each other, and if any one of these was missing, both the restoration property and the bending property cannot be achieved.

<<Second Example Group>>

Next, an example related to the flexible image display device member II proposed by the present invention will be described.

<Raw Materials>

First, raw materials of the resin composition prepared in Examples and Comparative Examples will be described in detail.

1. Acrylic (co)polymer
Acrylic copolymer (mass average molecular weight: about 700,000) composed of 2-ethylhexyl acrylate, methyl acrylate, ethyl acrylate, 2-hydroxyethyl acrylate, and 4-hydroxyacrylate

2. Curable compound
Urethane acrylate: a propylene glycol skeleton-containing monofunctional urethane acrylate, PEM-X264 (manufactured by AGC), mass average molecular weight: about 10,000, glass transition temperature: −53° C.

3. Isocyanate raw material
Trixene block isocyanate number “7982” manufactured by Baxenden Co., Ltd.

4. Thermosetting catalyst
“K-KAT XK672” manufactured by Kusumoto Chemicals, Ltd. (a catalyst containing Zn and Zr as metal components)

5. Radical initiator
4-methylbenzophenone (hydrogen abstraction type initiator)

6. Silane coupling agent
“KBM403” manufactured by Shin-Etsu Chemical Co., Ltd.

7. Rust inhibitor
1,2,3-benzotriazole

8. Solvent
Ethyl acetate

9. Acrylic adhesive sheet
Commercially available acrylic adhesive sheet (thickness: 50 μm)

TABLE 3

| | | | | Comparative | Comparative |
|---|---|---|---|---|---|
| | | Example II-1 | Example II-2 | Example II-1 | Example II-2 |
| Acrylic polymer | Parts | 100 | 100 | | 100 |
| Curable compound | by | 25 | 25 | | |
| Isocyanate raw material | mass | | | | 3 |
| Thermosetting catalyst | | | | | 0.5 |
| Radical initiator | | 3 | 3 | | |
| Silane coupling agent | | 0.3 | 0.3 | | |
| Rust inhibitor | | 0.3 | 0.3 | | 0.3 |
| Acrylic adhesive sheet | | | | 100 | |
| Solvent | | No | Ethyl acetate | | Ethyl acetate |
| UV irradiation dose | J/cm² | 3 | 1 | 2 | No irradiation |

[Preparation II-1 of Adhesive Sheet]

In Comparative Example II-1, an adhesive sheet was obtained as follows.

The commercially available acrylic adhesive sheet was developed on a release film (PET film, manufactured by Mitsubishi Chemical Corporation) having a thickness of 100 μm, which had been subjected to a silicone release treatment.

Next, a release film (PET film, manufactured by Mitsubishi Chemical Corporation) having a thickness of 75 μm, which had been subjected to a silicone release treatment, was layered on the acrylic adhesive sheet to form a layered body, and light irradiation was performed on the acrylic adhesive sheet through the release film by using a metal halide lamp irradiation device (UVC-0516S1, lamp UVL-8001M3-N, manufactured by Ushio Inc.) such that a total irradiation amount at a wavelength of 365 nm was 2000 mJ/cm², thereby obtaining an adhesive sheet layered body in which release films were layered on both front and back sides of an adhesive sheet (sample) having a thickness of 50 urn.

[Preparation II-2 of Adhesive Sheet]

In Examples II-1 and 11-2, each of adhesive sheets was obtained as follows.

The raw materials were blended in a mass ratio shown in Table 3 to prepare a resin composition containing a solvent, and the resin composition was developed into a sheet shape such that the thickness of the resin composition was 220 μm on the release film having a thickness of 100 μm, which had been subjected to a silicone release treatment.

Next, the sheet-shaped resin composition together with the release film was placed into a dryer heated to 90° C. and held for 10 minutes, and the solvent contained in the resin composition was volatilized.

Further, the release film having a thickness of 75 μm, which had been subjected to a silicone release treatment, was layered on the sheet-shaped resin composition obtained by drying the solvent to form a layered body, and light irradiation was performed on the resin composition through the release film by using a metal halide lamp irradiation device (UVC-0516S1, lamp UVL-8001M3-N, manufactured by Ushio Inc.) such that a total irradiation amount at a wavelength of 365 nm was the value shown in Table 3, thereby obtaining an adhesive sheet layered body in which release films were layered on both front and back sides of a 50 μm adhesive sheet (sample).

[Preparation 11-3 of Adhesive Sheet]

In Comparative Example 11-2, an adhesive sheet was obtained as follows.

The raw materials were blended in a mass ratio shown in Table 3 to prepare a resin composition containing a solvent, and the resin composition was developed into a sheet shape such that the thickness of the resin composition was 220 μm on the release film having a thickness of 100 μm, which had been subjected to a silicone release treatment.

Next, the sheet-shaped resin composition together with the release film was placed into a dryer heated to 90° C. and held for 10 minutes, and the solvent contained in the resin composition was volatilized. Further, the release film having a thickness of 75 μm, which had been subjected to a silicone release treatment, was layered on the sheet-shaped resin composition obtained by drying the solvent to form a layered body, and the layered body was placed into an electric furnace heated to 140° C. and held for 60 minutes for a heat treatment, thereby obtaining an adhesive sheet layered body in which release films were layered on both front and back sides of a 50 μm adhesive sheet (sample).

[Measurement and Evaluation for Adhesive Sheet]

Measurement and evaluation for the adhesive sheets (samples) obtained in Examples and Comparative Examples were performed as follows.

<Creep Compliance>

The release film was removed from each of the adhesive sheet layered bodies prepared in Examples and Comparative Examples, and a plurality of adhesive sheets (samples) were layered to form a layered body having a thickness of 1.0 mm. A cylinder (height: 1.0 mm) having a diameter of 8 mm was punched out from the obtained layered body of the adhesive layer, and was used as a sample. For the above sample, the creep compliance J(t) (MPa⁻¹) was measured by using a viscoelasticity measurement device (product name “DHR 1” manufactured by T.A. Instruments) and continuously applying a stress of 3,000 Pa under the following conditions. From a measurement result thereof, a value when the stress of 3,000 Pa was applied was set as a minimum creep compliance J(t)min (MPa⁻¹), and a maximum creep compliance J(t)max (MPa⁻¹) measured until 3757 seconds after the minimum creep compliance J(t)min was measured was derived.

(Measurement Conditions)
Adhesive jig: parallel plate having a diameter of 8 mm
Measurement temperature: 25° C.

<Storage Shear Modulus (G′) and Loss Tangent (tan δ)>

The release film was removed from each of the adhesive sheet layered bodies prepared in Examples and Comparative Examples, and a plurality of adhesive sheets (samples) were layered to form a layered body having a thickness of 1.0 mm. A cylinder (height: 1.0 mm) having a diameter of 8 mm was punched out from the obtained layered body of the adhesive layer, and was used as a sample. For the above sample, the storage shear modulus (G′) and the loss tangent (tan δ) were measured by using a viscoelasticity measurement device (product name “DHR 1” manufactured by T.A. Instruments) under the following measurement conditions.

From the obtained data, the maximum value of the loss elastic modulus in a temperature range of −60° C. to 25° C. (tan δ (max)), the storage shear modulus at −20° C. G′ (−20° C.), the storage shear modulus at 60° C. G′ (60° C.), and the temperature at which a maximum point of the loss tangent (tan δ) appeared (glass transition temperature (Tg)) were obtained.

(Measurement Conditions)

Adhesive jig: parallel plate having a diameter of 8 mm

Distortion: 0.1%

Frequency: 1 Hz

Measurement temperature: −60° C. to 100° C.

Temperature rising rate: 5° C./min

<Gel Fraction>

The release film was removed from each of the adhesive sheet layered bodies prepared in Examples and Comparative Examples, about 0.1 g of the adhesive sheet (sample) was collected, soaked in ethyl acetate for 24 hours, and dried at 75° C. for 4.5 hours, and then a mass fraction of the remaining gel component was obtained and used as the gel fraction.

<Metal Component Content>

About 0.2 g of an adhesive resin was weighed into a Teflon (registered trademark) decomposition container, nitric acid for electronic industry was added, pressure decomposition was performed by using a microwave decomposition device ETHOS-UP manufactured by Milestone General K. K., and then ultrapure water purified by an ultrapure water production device manufactured by Merck Co., Ltd. with a total volume of 50 ml was used as a test solution.

For the above test solution, by using a high-frequency inductively coupled plasma emission spectrometer (ICP-AES) manufactured by Agilent Technologies, the metal components in the adhesive were quantified by a high-frequency inductively coupled plasma emission spectroscopy method and an absolute calibration curve method.

As the metal component content, a total amount of elements detected at a quantification lower limit (50 ppm) or more was used.

[Preparation of Layered Sheet]

The release film of each of the adhesive sheet layered bodies prepared in Examples and Comparative Examples was removed, and a first member sheet and a second member sheet were bonded to both surfaces of the adhesive sheet (sample) with a hand roll to obtain a layered sheet (sample).

At this time, in Examples and Comparative Examples, a polyimide film (“UPILEX 50S” manufactured by Ube Industries, Ltd., thickness: 50 μm) was used as the first member sheet and the second member sheet.

[Evaluation for Layered Sheet]

The layered sheet (sample) prepared as described above by using each of the adhesive sheets (samples) obtained in Examples and Comparative Examples was evaluated as follows.

<Impact Resistance Test>

The release films on both surfaces of the layered sheet (sample) were removed, and a polyimide film (“UPILEX 50S” manufactured by Ube Industries, Ltd., thickness: 50 μm) was bonded to both surfaces of the adhesive sheet (sample) with a hand roller, thereby preparing a layered body composed of polyimide film/adhesive sheet (sample)/polyimide film. The prepared layered body was layered on a pressure-sensitive paper provided on a metal plate. Further, a stainless steel ball (5 g) was prepared, and the stainless steel ball was dropped on the layered body from a predetermined height. After dropping, the layered body was removed from the pressure-sensitive paper, and the number of times of bound of the ball recorded on the pressure-sensitive paper was counted.

Drop height: 5 cm

Evaluation: “A”: when the number of times of bound was 1 or less, the impact resistance was good.

Evaluation: “B”: when the number of times of bound was 2 or more, the impact resistance was insufficient.

<Residual Distortion Test>

The release films on both surfaces of the layered sheet (sample) were removed, and a polyimide film (“UPILEX 50S” manufactured by Ube Industries, Ltd., thickness: 50 μm) was bonded to both surfaces of the adhesive sheet (sample) with a hand roller, thereby preparing a layered body composed of polyimide film/adhesive sheet (sample)/polyimide film. The prepared layered body was bent at a radius of curvature R of 3 mm, and stored at room temperature (23° C.) for 3 hours, and then the jig was released to evaluate the restoration property. Similarly, when the restoration property of only the member sheet (CPI film) was confirmed, the inner angle of the film was restored to 90° or more 5 seconds after the jig was released.

Evaluation: “A”: the inner angle of the film was restored to 90° or more 5 seconds after the jig was released.

Evaluation: “B”: the inner angle of the film was not restored to 90° or more 5 seconds after the jig was released.

<Corrosion Resistance Test>

One of the release films was removed from each of the adhesive sheet layered bodies prepared in Examples and Comparative Examples, and a polyethylene terephthalate film (“Cosmo shine A4300” manufactured by Toyobo Co., Ltd., thickness: 100 μm) as a backing film was roll-bonded to the adhesive sheet (sample) with a hand roller. Subsequently, the other release film was removed, and roll-bonded, with a hand roller, to a silver nanowire coating surface of a silver nanowire (diameter: 40 nm) sheet manufactured by TPK. The other release film was placed in a thermo-hygrostat controlled to 85° C. and 85% RH, and an increase rate of a sheet resistance value after 300 hours was measured.

For the measurement of the sheet resistance value, “EC-80” manufactured by Napson Corporation was used. The evaluation was performed according to the following evaluation criteria.

Evaluation “A”: the increase rate of the sheet resistance value was less than 10% after 300 hours.

Evaluation “B”: the increase rate of the sheet resistance value was 10% or more after 300 hours.

In the following dynamic and static bending tests, a CPI film (main component: transparent polyimide, “C_50” manufactured by KOLON, 25° C. tensile strength: 307 MPa) was used as the first member sheet and the second member sheet of the layered body.

Results obtained by the measurement and evaluation for the adhesive sheet and the layered sheet are shown in Table 4.

TABLE 4

| | | | | | Comparative |
|---|---|---|---|---|---|
| | | | Example II-1 | Example II-2 | Example II-1 |
| Adhesive | ΔlogJ(t) creep compliance | | 0.8 | 0.9 | 1.5 |
| sheet | fluctuation value | | | | |
| | tan δ (Max) | | 1.8 | 1.8 | 1.4 |
| | Temperature of tan δ (Max) | ° C. | −37 | −38 | −18 |
| | G′ (60° C.) | MPa | 0.01 | 0.01 | 0.02 |
| | tan δ (60° C.) | | 0.43 | 0.49 | 0.60 |
| | G′ (−20° C.) | MPa | 0.2 | 0.2 | 2.6 |
| | Gel fraction | % | 73 | 71 | 71 |
| | Metal component content | ppm | 350 | 350 | Unmeasured |
| Layered | Impact resistance test | Number of | 1 | 1 | 2 |
| sheet | | times of | | | |
| | | bound | | | |
| | | Evaluation | A | A | A |
| | Residual distortion test | Evaluation | A | A | B |
| | (restoration property) | | | | |
| | Corrosion resistance test | Evaluation | A | A | Unevaluated |

The layered sheets of Examples II-1 and 11-2 in which the maximum value (tan δ (max)) of the loss elastic modulus in the temperature range of −60° C. to 25° C. obtained by the dynamic viscoelasticity measurement in the shear mode at a frequency of 1 Hz was 1.5 or more and the creep compliance fluctuation value Δ log J(t) was less than 1.0 exhibited good results in the impact resistance test and the residual distortion test. Further, the layered sheets of Examples II-1 and II-2 exhibited a good restoration property also in the dynamic bending test and the static bending test.

However, in the layered sheet of Comparative Example 1 in which the creep compliance fluctuation value Δ log J(t) was 1.0 or more, a good result was not obtained in the residual distortion test. Further, in Comparative Example II-1 in which the maximum value (tan δ (max)) of the loss elastic modulus in the temperature range of −60° C. to 25° C. obtained by the dynamic viscoelasticity measurement in the shear mode at a frequency of 1 Hz was less than 1.5, a good result was not obtained in the impact resistance test.

In the adhesive sheet of Comparative Example 11-2 obtained by a thermal crosslinking reaction of isocyanate, the metal component content was as high as 1800 ppm due to the metal component contained in the catalyst necessary for the thermal crosslinking reaction, and the increase rate of the resistance value of the sheet was 10% or more after 300 hours in the metal corrosion resistance test, resulting in a defect. Therefore, the adhesive sheet of Comparative Example 11-2 was not evaluated in the impact resistance test and the residual distortion test.

1. A flexible image display device member having a configuration in which two flexible members are bonded together via an adhesive layer, wherein
the adhesive layer satisfies requirements (1) and (2):
(1) a storage shear modulus at 60° C. (G′ (60° C.)) obtained by dynamic viscoelasticity measurement in a shear mode at a frequency of 1 Hz is 0.005 MPa or more and less than 0.20 MPa, and a loss tangent at 60° C. (tan δ (60° C.)) is less than 0.60; and
(2) when a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

2. A flexible image display device member having a configuration in which two flexible members are bonded together via an adhesive layer, wherein
the adhesive layer satisfies requirements (3) and (4):
(3) a maximum value (tan δ (max)) of a loss elastic modulus in a temperature range of −60° C. to 25° C. obtained by dynamic viscoelasticity measurement in a shear mode at a frequency of 1 Hz is 1.5 or more; and
(4) when a creep compliance value measured when a stress of 3,000 Pa is applied is set to a minimum creep compliance J(t)min (MPa⁻¹), and a maximum creep compliance value measured during a period in which the stress of 3,000 Pa continues to be applied until 3757 seconds after the minimum creep compliance J(t)min is measured is set to a maximum creep compliance J(t)max (MPa⁻¹), a creep compliance fluctuation value Δ log J(t) calculated based on a difference between the minimum creep compliance J(t)min and the maximum creep compliance J(t)max is less than 1.0.

3. The flexible image display device member according to claim 1 or 2, wherein
the adhesive layer has a storage shear modulus at −20° C. (G′ (−20° C.)) of 1.0 MPa or less obtained by the dynamic viscoelasticity measurement in the shear mode at a frequency of 1 Hz.

4. The flexible image display device member according to any one of claims 1 to 3, wherein
the adhesive layer has a maximum point of the loss tangent at −25° C. or lower obtained by the dynamic viscoelasticity measurement in the shear mode at a frequency of 1 Hz.

5. The flexible image display device member according to any one of claims 1 to 4, wherein
the adhesive layer has a gel fraction of 70% or more.

6. The flexible image display device member according to any one of claims 1 to 5, wherein
the adhesive layer is formed of a resin composition containing a urethane acrylic (co)polymer.

7. The flexible image display device member according to claim 6, wherein
the urethane acrylic (co)polymer contains a polyfunctional urethane (meth)acrylate as a monomer component.

8. The flexible image display device member according to any one of claims 1 to 7, wherein
the adhesive layer is formed of a resin composition containing an acrylic (co)polymer having a (meth)acrylate as a monomer component and a curable compound.

9. The flexible image display device member according to claim 8, wherein
the resin composition contains a radical initiator.

10. The flexible image display device member according to claim 8 or 9, wherein
the curable compound is a urethane (meth)acrylate.

11. The flexible image display device member according to any one of claims 1 to 10, wherein
the adhesive layer has a content of a metal element of less than 1000 ppm.

12. The flexible image display device member according to claim 11, wherein
the metal element is one or more selected from the group consisting of Fe, Zn, Zr, Bi, Al, and Sn.

13. The flexible image display device member according to any one of claims 1 to 12, wherein
at least one of the two flexible members satisfies a requirement (5):
(5) tensile strength at 25° C. measured according to ASTM D882 is 10 MPa to 900 MPa.

14. The flexible image display device member according to any one of claims 1 to 13, wherein
at least one of the two flexible members has one or more resins selected from the group consisting of a cycloolefin resin, a triacetyl cellulose resin, a polymethyl methacrylate resin, an epoxy resin, and a polyimide resin as main components.

15. A flexible image display device comprising:
the flexible image display device member according to any one of claims 1 to 14.
